(19) United States
(12) Patent Application Publication
(10) Pub. No.: US 2006/0017517 A1
(43) Pub. Date: Jan. 26, 2006

(54) Voltage controlled oscillator

(76) Inventors: Takashi Ootsuka, Yokohama-shi (JP); Hisato Takeuchi, Yokohama-shi (JP); Keigo Shingu, Suginami-ku (JP)

Correspondence Address: RATNERPRESTIA, P.O. BOX 980, VALLEY FORGE, PA, 19482, US

(21) Appl. No.: 11/188,326

(22) Filed: Jul. 25, 2005

(30) Foreign Application Priority Data
Jul. 23, 2004 (JP) 2004-215581

(51) Int. Cl. H03B 5/32

(52) U.S. Cl. 331/158

(57) ABSTRACT

A voltage controlled oscillator enables controlling the MOS transistor threshold voltage independently of the temperature compensation control signal and external voltage frequency control signal. The voltage controlled oscillator has a crystal oscillator and a load capacitance is parallel connected to a crystal oscillator. The load capacitance includes a first MOS transistor comprising a gate terminal and a source/drain terminal formed by shorting the source and drain, and a second MOS transistor comprising a gate terminal and a source/drain terminal formed by shorting the source and drain. First and second control signal generating circuits supply respective control signals to the source/drain terminals and gate terminals of the first and second MOS transistors.

### BACKGROUND OF THE INVENTION

1. Field of Technology

The present invention relates to a voltage controlled oscillator which is used as a voltage controlled temperature compensated crystal oscillator.

2. Description of Related Art

A temperature compensated crystal oscillators is a type of crystal oscillator that is used as a reference frequency source in cell phones and other electronic devices, and reduces change in output frequency resulting from temperature variations. A voltage controlled oscillator is a type of oscillator that can change the load capacity and control the output frequency by providing a variable capacitor, which can change the capacitance by means of voltage, as a load capacitance in the oscillation loop and controlling the terminal voltage of this variable capacitance. A temperature compensated crystal oscillator controls the terminal voltage of the variable capacitance in a voltage controlled oscillator to cancel the temperature characteristic of the crystal vibrator (piezoelectric vibrator).

Temperature compensated crystal oscillators have benefited from advances in phase noise reduction, a shorter startup time, high precision temperature compensation, and size reduction. Reducing the size of the crystal vibrator is essential to reducing the size of a crystal oscillator. In general, however, reducing the size of the crystal vibrator tends to reduce the change in frequency for a given change in variable capacitance. This makes it necessary to increase the capacitance change relative to the control voltage of the variable capacitance used as the load capacitance. Japanese Unexamined Patent Application Publication 2003-318417 (see FIG. 11), for example, teaches increasing the change in capacitance relative to a change in the control voltage as a result of using the electrostatic capacitance produced between the gate and the source/drain terminal of a MOS transistor of which the source and drain terminals are shorted to form a single terminal, thereby improving the sensitivity of frequency change in the crystal oscillator.

See also Japanese Unexamined Patent Application Publication H11-220329.

When the electrostatic capacitance produced between the gate and the source/drain terminal of a MOS transistor is directly connected to the amplifier and crystal vibrator (piezoelectric vibrator) as the variable capacitance of a voltage controlled oscillator and the frequency is controlled by controlling the gate voltage of the MOS transistor, a channel is formed directly below the gate oxidation layer when the gate voltage of the MOS transistor goes to the source/drain terminal voltage plus the threshold voltage, and the electrostatic capacitance of the gate and the channel, that is, the source/drain terminal, increases. The gate voltage in this situation is defined as the capacitance switching voltage.

A first problem with the foregoing art is that because the dc bias of the source/drain terminal is determined on the amplifier side of the oscillator circuit, the capacitance switching voltage cannot be set as desired and the frequency cannot be controlled around a desired gate voltage.

A second problem is that the capacitance switching voltage is dependent upon the temperature characteristic and variation in the threshold voltage of a MOS transistor manufactured in a conventional CMOS process, but the temperature compensation control signal and the external voltage frequency control signal in the prior art must be able to cancel the temperature characteristic and threshold voltage variation of the MOS transistor.

As a result, the threshold voltage control signal of the MOS transistor must be controllable independently of the temperature compensation control signal and external voltage frequency control signal in order to simplify the practical design and application of a crystal oscillator which uses the electrostatic capacitance produced between the source/drain and gate terminals of the MOS transistor.

An object of the present invention is thus to provide a voltage controlled oscillator which can control the threshold voltage of the MOS transistor independently of the temperature compensation control signal and external voltage frequency control signal in order to achieve an oscillator that uses the electrostatic capacitance produced between the source/drain and gate terminals of a MOS transistor of which the source and drain are shorted in a voltage controlled oscillator.

### SUMMARY OF THE INVENTION

To achieve the foregoing object, according to a first aspect of the present invention, a voltage controlled oscillator having a pair of terminals for connection to a piezoelectric vibrator comprises:

an amplifier of which the input and output sides are separately connected to the terminals of the terminal pair for connection to the piezoelectric vibrator;

a MOS transistor having source, drain, and gate terminals with the source terminal connected to the drain terminal;

a capacitance element inserted between one side of the amplifier and the source terminal of the MOS transistor;

a first control signal generating circuit operable to supply an electric control signal to the source terminal of the MOS transistor; and

a second control signal generating circuit operable to supply an electric control signal to the gate terminal of the MOS transistor.

According to a second aspect of the invention, a voltage controlled oscillator having a pair of terminals for connection to a piezoelectric vibrator, comprises:

an amplifier of which the input and output sides are separately connected to the terminals of the terminal pair for connection to the piezoelectric vibrator;

first and second MOS transistors each having source, drain, and gate terminals with the source terminal connected to the drain terminal;

a first capacitance element inserted between one side of the amplifier and the source terminal of the first MOS transistor;

a second capacitance element inserted between one side of the amplifier and the source terminal of the second MOS transistor;

a first control signal generating circuit operable to supply an electric control signal to the source terminal of at least one of the first and second MOS transistors; and

a second control signal generating circuit operable to supply an electric control signal to the gate terminal of at least one of the first and second MOS transistors.

According to a preferred embodiment, the first and second capacitance elements are commonly connected to one side of the amplifier.

According to a third aspect of the invention, a voltage controlled oscillator having a pair of terminals for connection to a piezoelectric vibrator, comprises:

an amplifier of which the input and output sides are separately connected to the terminals of the terminal pair for connection to the piezoelectric vibrator;

first and second MOS transistors each having source, drain, and gate terminals with the source terminal connected to the drain terminal;

a first capacitance element inserted between one side of the amplifier and the source terminals of the first and second MOS transistors;

a second capacitance element inserted between the other side of the amplifier and the gate terminal of the first MOS transistor;

a third capacitance element inserted between the other side of the amplifier and the gate terminal of the second MOS transistor;

a first control signal generating circuit operable to supply an electric control signal to the source terminal of at least one of the first and second MOS transistors; and

a second control signal generating circuit operable to supply an electric control signal to the gate terminal of at least one of the first and second MOS transistors.

According to a preferred embodiment, the voltage controlled oscillator further comprises a third control signal generating circuit operable to supply an electric control signal to the gate terminal of at least one of the first and second MOS transistors.

According to a fourth aspect of the invention, a voltage controlled oscillator having a pair of terminals for connection to a piezoelectric vibrator, comprises:

an amplifier of which the input and output sides are separately connected to the terminals of the terminal pair for connection to the piezoelectric vibrator;

first, second, third, and fourth MOS transistors each having source, drain, and gate terminals with the source terminal connected to the drain terminal;

a first capacitance element inserted between one side of the amplifier and the source terminals of the first and second MOS transistors;

a second capacitance element inserted between the other side of the amplifier and the source terminals of the third and fourth MOS transistors;

a first control signal generating circuit operable to supply an electric control signal to the source terminals of either the first and second MOS transistor pair or the third and fourth MOS transistor pair;

a second control signal generating circuit operable to supply an electric control signal to the gate terminal of at least one of the first and third MOS transistors; and

a third control signal generating circuit operable to supply an electric control signal to the gate terminal of at least one of the second and fourth MOS transistors.

According to a preferred embodiment, the voltage controlled oscillator has a piezoelectric vibrator connected to the terminals for connection to a piezoelectric vibrator.

According to a preferred embodiment, the piezoelectric vibrator is a crystal vibrator.

According to a preferred embodiment, the first control signal is a signal containing at least one of a temperature compensation control signal, external voltage frequency control signal, and deviation compensation control signal.

According to a preferred embodiment, the second control signal is a signal containing at least one of a temperature compensation control signal, external voltage frequency control signal, and deviation compensation control signal.

According to a preferred embodiment, the third control signal is a signal containing at least one of a temperature compensation control signal, external voltage frequency control signal, and deviation compensation control signal.

According to a preferred embodiment, the voltage controlled oscillator further comprises an amplitude control circuit disposed to the source/drain terminal of the first MOS transistor, or to the source/drain terminal of the second MOS transistor.

According to a preferred embodiment, the voltage controlled oscillator further comprises a variation cancellation circuit disposed to the first control signal generating circuit or to the second control signal generating circuit.

According to a preferred embodiment, the voltage controlled oscillator further comprises a controller having memory storing a table for variation cancellation disposed to the first control signal generating circuit or the second control signal generating circuit.

According to a preferred embodiment, the variation cancellation circuit comprises a third MOS transistor configured substantially identically to the first or second MOS transistor, and applies to the drain terminal of the first MOS transistor or second MOS transistor a voltage generated by inverting and amplifying current generated by the third MOS transistor.

A voltage controlled oscillator according to the present invention can thus control the capacitance switching voltage independently of the temperature compensation control signal and the external voltage frequency control signal, and can thus vary the frequency around a desired control voltage.

The present invention further advantageously enables inputting a signal for cancelling threshold voltage variation and the temperature characteristic of the MOS transistor independently of the temperature compensation control signal and the external voltage frequency control signal, simplifying the design of a temperature compensation control circuit and an external voltage frequency control circuit, and achieving a voltage controlled oscillator that uses the electrostatic capacitance produced between the source/drain and gate terminals of a MOS transistor of which the source and drain are shorted.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1 is a schematic circuit diagram showing a voltage controlled oscillator according to a first embodiment of the present invention;

FIG. 2A is a waveform diagram of signals at major points in the circuit of the first embodiment of the invention;

FIG. 2B shows the C-V characteristic and f-V characteristic describing the first embodiment of the present invention;

FIG. 3 is a schematic circuit diagram showing a voltage controlled oscillator according to a first variation of the first embodiment of the present invention;

FIG. 4 is a schematic circuit diagram showing a voltage controlled oscillator according to a second variation of the first embodiment of the present invention;

FIG. 5A is a schematic circuit diagram showing a voltage controlled oscillator according to a second embodiment of the present invention;

FIG. 5B is a schematic circuit diagram showing a voltage controlled oscillator according to a first variation of the second embodiment of the present invention;

FIG. 6A is a waveform diagram of signals at major points in the circuit of the second embodiment of the invention;

FIG. 6B shows the C-V characteristic and f-V characteristic describing the second embodiment of the present invention;

FIG. 7 is a schematic circuit diagram showing a voltage controlled oscillator according to a first variation of the second embodiment of the present invention;

FIG. 8 is a schematic circuit diagram showing a voltage controlled oscillator according to a second variation of the second embodiment of the present invention;

FIG. 9 is a schematic circuit diagram showing a voltage controlled oscillator according to a third embodiment of the present invention;

FIG. 10 is a schematic circuit diagram showing a voltage controlled oscillator according to a variation of the third embodiment of the present invention; and

FIG. 11 is a schematic circuit diagram showing a voltage controlled oscillator according to the prior art.

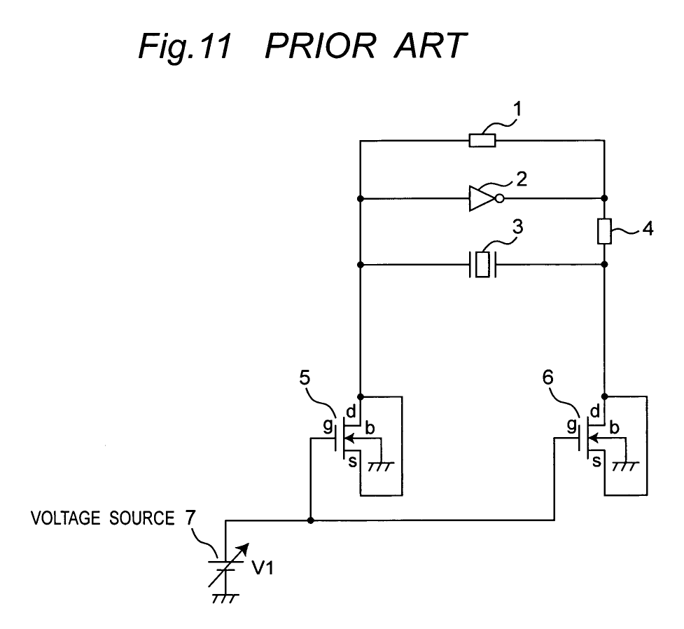

### DETAILED DESCRIPTION OF THE PREFERRED EMBODIMENTS

Preferred embodiments of the present invention are described below with reference to the accompanying figures.

### Embodiment 1

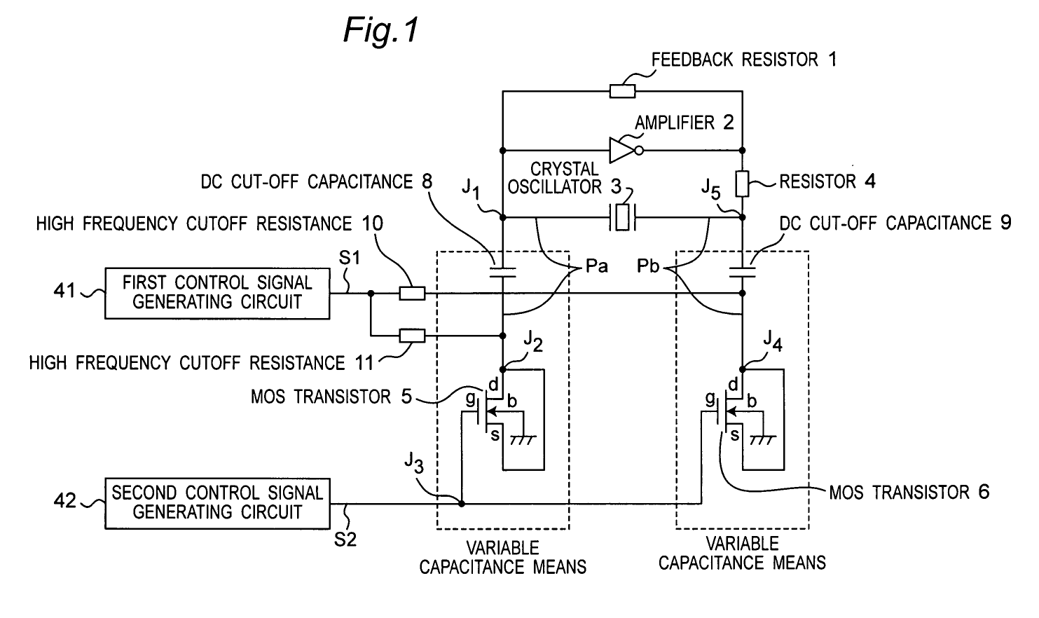

FIG. 1 is a circuit diagram showing the arrangement of a voltage controlled oscillator according to a first embodiment of the present invention. MOS transistors 5 and 6 are used as a variable capacitance in this first embodiment of the invention. Using MOS transistor 5 by way of example, the source s and drain d are shorted and the back gate b goes to ground. As described below, the capacitance between the source/drain and gate is variable. MOS transistor 5 is thus used as a variable capacitance device in the present invention. MOS transistor 6 is identical to MOS transistor 5.

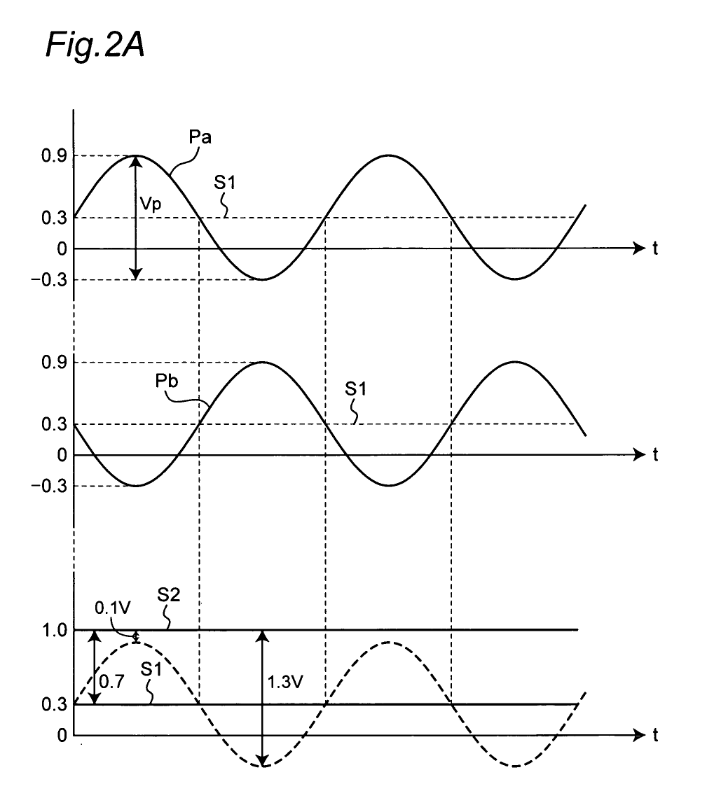

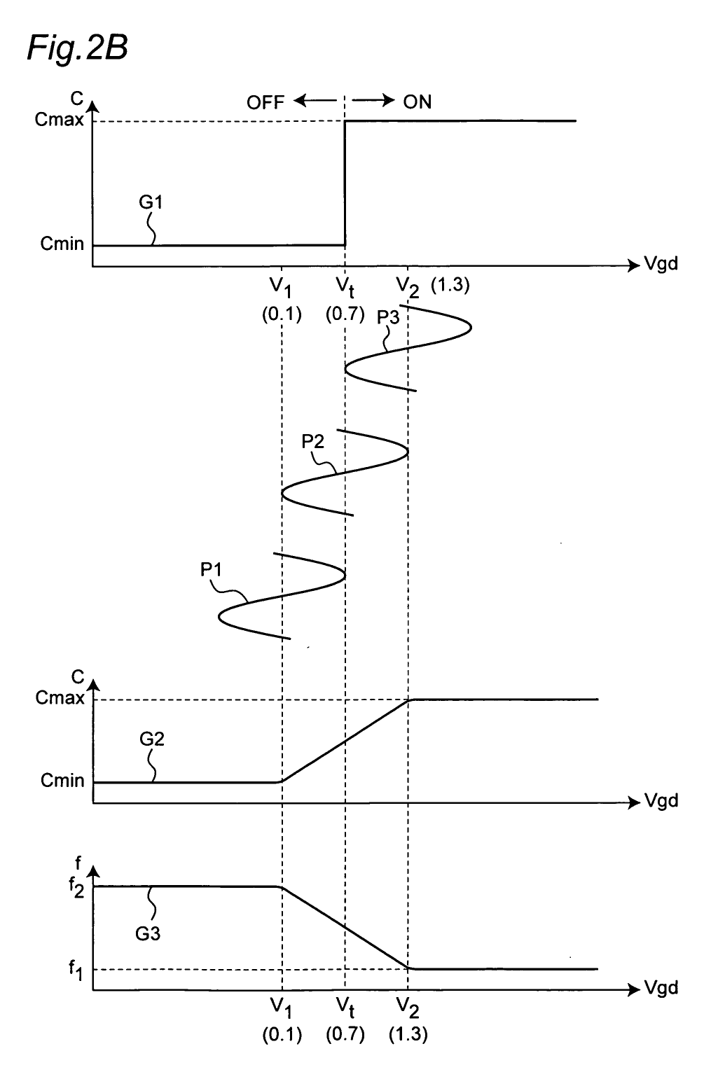

As shown in FIG. 1, the oscillator circuit is composed of a feedback resistor 1 constituting a feedback circuit, an amplifier 2, and a crystal oscillator 3. The load capacitance of the oscillator circuit is the capacitance of the oscillation loop, which is the closed loop from one terminal of the crystal oscillator 3 to node J1, DC cut-off capacitance 8, node J2, MOS transistor 5, node J3, MOS transistor 6, node J4, and back to the other terminal of the crystal oscillator 3. The DC cut-off capacitance 8 and MOS transistor 5 form a first variable capacitance means, and DC cut-off capacitance 9 and MOS transistor 6 form a second variable capacitance means. The first variable capacitance means and second variable capacitance means have the same IC structure. Oscillation of the crystal oscillator 3 produces a sine wave signal with 180° opposite phase at the two terminals of the crystal oscillator 3. As a result, sine signal Pa shown in FIG. 2A appears on the line from one terminal of the crystal oscillator 3 to node J1, DC cut-off capacitance 8, and node J2, and sine signal Pb appears on the line from the other terminal of the crystal oscillator 3 to J5, DC cut-off capacitance 9, and node J4. Because the gates of MOS transistors 5 and 6 are mutually connected at node J3, the signal appearing at node J3 is the superposed sum signal of sine signals Pa and Pb, which in this case is a flat DC signal because sine signals Pa and Pb are mutually cancelling. Node J3 is thus alternately grounded, and can thus also be called an AC ground terminal.

A first control signal generating circuit 41 is connected to the source/drain terminal of MOS transistor 6 through high frequency cutoff resistance 10, and is connected to the source/drain terminal of MOS transistor 5 through high frequency cutoff resistance 11.

A second control signal generating circuit 42 is connected to the gate of MOS transistor 5 and to the gate of MOS transistor 6.

The first control signal generating circuit 41 outputs first control signal S1, and second control signal generating circuit 42 outputs second control signal S2. Both control signals S1 and S2 are DC bias signals.

Operation of the voltage controlled oscillator shown in FIG. 1 is described next.

Waveform G1 in FIG. 2B denotes the C-V characteristic of MOS transistors 5 and 6 where the x-axis represents a voltage Vgd between the gate terminal and the source/drain terminal, and the y-axis represents an electrostatic capacitance between the source/drain terminal and gate terminal. The MOS transistors go ON when the voltage Vgd exceeds threshold voltage Vt. Electrostatic capacitance Cmax results between the source/drain terminal and gate terminal at this time. The MOS transistors turn OFF when the voltage Vgd becomes less than the threshold voltage Vt, at which time the electrostatic capacitance between the source/drain and gate disappears, that is, goes to Cmin.

What happens when the electrostatic capacitance of the MOS transistor is set to an apparent midpoint Cmid between Cmax and Cmin is described next with reference to real values. This situation is achieved when S2−S1=Vt.

It is assumed below that the threshold voltage Vt at which the MOS transistor changes from ON to OFF is 0.7 V, the peak-to-peak amplitude Vp of sine signals Pa and Pb is 1.2 V, the DC bias voltage of the first control signal S1 from first control signal generating circuit 41 is 0.3 V, and the DC bias voltage of the second control signal S2 from second control signal generating circuit 42 is 1.0 V, that is, S2−S1=Vt (0.7 V) as shown at the bottom in FIG. 2A. As shown at the top and middle in FIG. 2A, sine signals Pa and Pb both oscillate around 0.3 V. A sine wave that changes from −0.3 V to 0.9 V is thus applied to the source/drain terminal of the MOS transistors 5 and 6 while 1.0 V is applied to the gate of each MOS transistor. The potential difference between the source/drain and gate terminals of the of the MOS transistors is thus a sine wave oscillating between 1.3 V and 0.1 V with a center at 0.7 V (=S2−S1) as denoted by sine wave P2 in FIG. 2B. The MOS transistors thus switch repeatedly on/off with a duty cycle of 50%. Observing this over a period of time shows that the electrostatic capacitance between the source/drain and gate terminals of the MOS transistors is Cmid=(Cmax+Cmin)/2, that is, precisely half way between Cmax and Cmin.

The situation in which the electrostatic capacitance of the MOS transistor is set to greater than midpoint Cmid is described next. The condition for this situation is that S2−S1>Vt. Using the foregoing specific values, this situation occurs when S2 is changed from 1.0 V to 1.6 V. Because S2−S1=1.3 V in this case, the potential difference between the source/drain and gate terminals of the MOS transistor varies in a sine wave between 1.9 V and 0.7 V with a center at 1.3 V. This is denoted by sine wave P3 in FIG. 2B. In this situation the MOS transistor is ON with a duty cycle of 100%. The electrostatic capacitance between the source/drain and gate terminals of the MOS transistor is therefore Cmax.

The situation in which the electrostatic capacitance of the MOS transistor is set to less than midpoint Cmid is described next. The condition for this situation is that S2−S1<Vt. Using the foregoing specific values, this situation occurs when S2 is changed from 1.0 V to 0.4 V. Because S2−S1=0.1 V in this case, the potential difference between the source/drain and gate terminals of the MOS transistor varies in a sine wave between 0.7 V and −0.6 V with a center at 0.1 V. This is denoted by sine wave P1 in FIG. 2B. In this situation the MOS transistor is ON with a duty cycle of 0%. The electrostatic capacitance between the source/drain and gate terminals of the MOS transistor is therefore Cmin.

By thus fixing S1 at 0.3 V and changing S2 linearly from 0.4 V to 1.6 V, the electrostatic capacitance of the MOS transistor also changes linearly from Cmin to Cmax. This linear change in the C-V characteristic is denoted by waveform G2 in FIG. 2B. The f-V characteristic of the oscillation frequency resulting from this linear change in the C-V characteristic is denoted by waveform G3 in FIG. 2B.

S1 is fixed and S2 is varied in the operation described above, but the same effect can be achieved when S1 is varied and S2 is fixed. The same effect can also be achieved by varying both S1 and S2. That is, if (S2−S1) ranges from 0.1 V to 1.3 V, the electrostatic capacitance of the MOS transistor can be linearly changed from Cmin to Cmax. This can be achieved by setting S1 and S2 to satisfy the following general expression.
Vt−(Vp/2)<S1−S2<Vt+(Vp/2)

S1 or S2 can thus be assigned the function of the temperature compensation control signal, external voltage frequency control signal, and variation compensation control signal (also called a variation cancellation signal).

Alternatively, S1 can be given the function of any one of the temperature compensation control signal, external voltage frequency control signal, and variation compensation control signal while S2 is given the function of the remaining signals. S1 and S2 could also be reversed in this arrangement.

The temperature compensation control signal is a signal which compensates for change in frequency due to a change in temperature.

The external voltage frequency control signal is a signal which controls the change in frequency relative to an externally applied voltage.

The variation cancellation signal is a signal which compensates for change in the threshold voltage due to variations during manufacture.

This is described next using the second control signal S2 from second control signal generating circuit 42 as the temperature compensation control signal and the first control signal S1 from first control signal generating circuit 41 as the variation cancellation signal.

The second control signal generating circuit 42 stores a table of temperature compensation voltage values, and outputs a predefined temperature compensation control signal S2. Variations from the manufacturing process in the voltage controlled oscillator also make it necessary to eliminate these variations. These variations can be cancelled using first control signal S1. If the predefined temperature compensation control signal S2 is applied when these manufacturing variations are cancelled, the desired temperature compensation can be achieved. It is therefore not necessary to set the temperature compensation control signal S2 specifically for each voltage controlled oscillator containing such variations, and control signal S2 can be set based on design conditions free of such variations. Variation from the design conditions of the specific voltage controlled oscillator can be cancelled using variation cancellation signal S1. The second control signal generating circuit 42 generating the temperature compensation control signal can therefore be designed independently, increasing design freedom and making design easier. This also applies to the first control signal generating circuit 41.

Because the MOS transistors have a variable capacitance in the present invention, a frequency change relative to the control voltage of 100 ppm or greater (a change of 5 KHz or more if operating at 50 MHz) can be achieved, thus assuring a range of frequency change for temperature compensation and external voltage frequency control that is compatible with a small crystal oscillator.

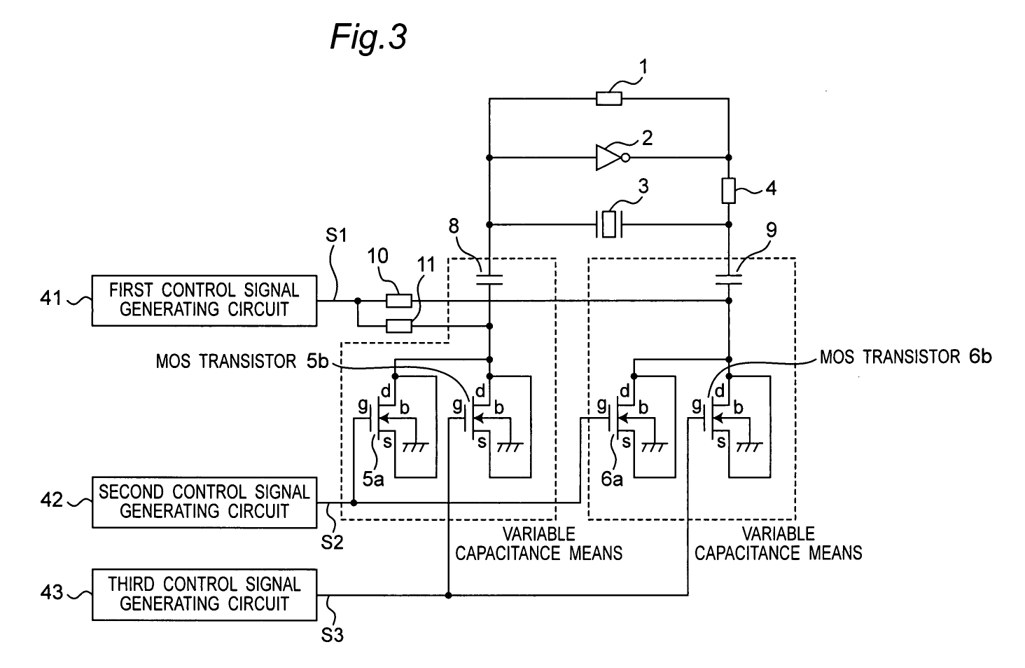

FIG. 3 shows a first variation of the first embodiment. As shown in FIG. 3 MOS transistor 5 is split into two MOS transistors 5a and 5b, and MOS transistor 6 is split into two MOS transistors 6a and 6b. As in the arrangement shown in FIG. 1, the gates of MOS transistors 5a and 6a are connected to the second control signal generating circuit 42. The gates of MOS transistors 5b and 6b, however, are connected to a new third control signal generating circuit 43. This third control signal generating circuit 43 outputs a DC level control signal S3. This arrangement enables assigning the functions of the temperature compensation control signal, external voltage frequency control signal, and variation compensation control signal to control signals S1, S2, and S3, respectively. The invention shall not be limited to this relationship, however, and the assignment of these compensation control signals to control signals S1 to S3 can be specified as desired.

By thus splitting the MOS transistors into plural MOS transistors as described in this first variation of the first embodiment, the capacitance switching voltage can be controlled more independently.

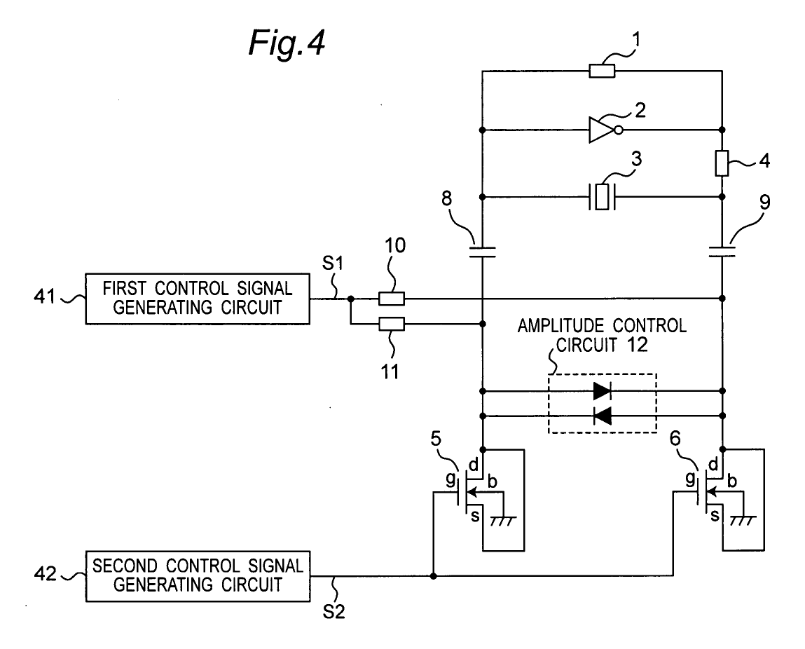

FIG. 4 shows a second variation of the foregoing first embodiment. As shown in FIG. 4, an amplitude control circuit 12 is connected between the source/drain terminal of the MOS transistor 5 and the source/drain terminal of the MOS transistor 6 in this second variation. As shown in the figure, the amplitude control circuit 12 can be composed of two diodes parallel connected in opposite directions.

If there is a sharp change in the load capacitance of the oscillation loop, the change in amplitude is prevented from changing more than the voltage controlled by the diodes, and good linearity can be achieved in the frequency-control voltage characteristic.

Note further that the DC cut-off capacitances 8 and 9 are connected between the crystal oscillator 3 and MOS transistors 5 and 6 in the present embodiment, but could be connected between the crystal oscillator 3 and amplifier 2.

The DC cut-off capacitances 8 and 9 could also be omitted.

### Embodiment 2

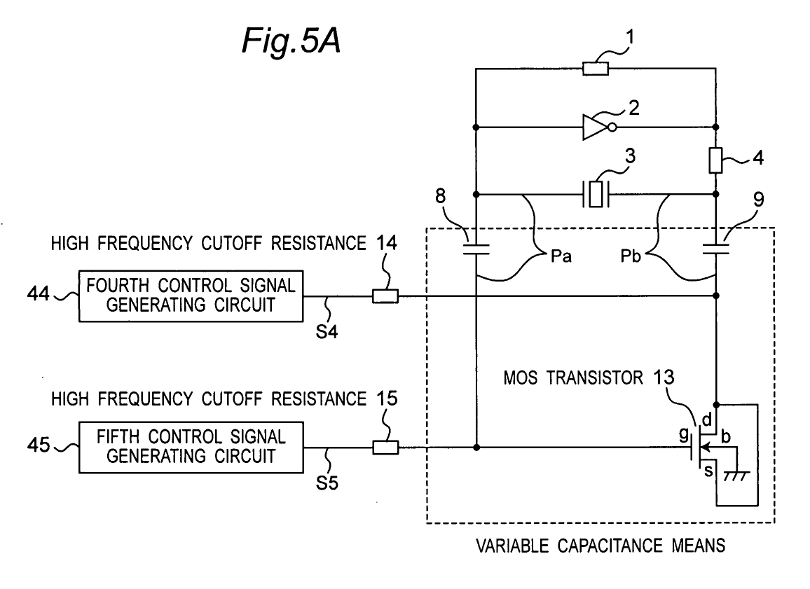

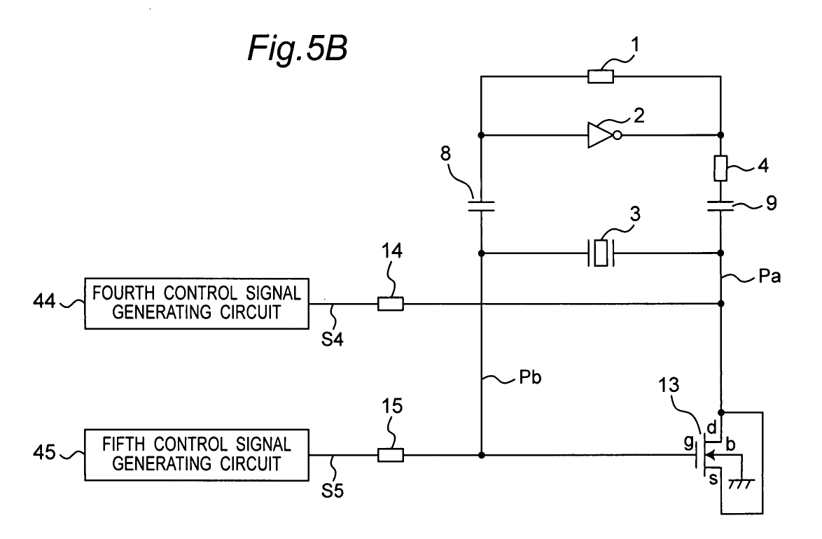

FIG. 5A is a schematic circuit diagram showing a voltage controlled oscillator according to a second embodiment of the present invention. As shown in FIG. 5A, the load capacitance of this oscillator circuit is the variable capacitance means composed of the first DC cut-off capacitance 8, variable capacitance MOS transistor 13, and a second DC cut-off capacitance 9 serial connected between the terminals of the crystal oscillator 3. The variable capacitance of this oscillator is the electrostatic capacitance produced between the source/drain and gate terminals of a MOS transistor 13 of which the source and drain are shorted. An arrangement in which an opposite phase oscillation voltage is applied to the source/drain and gate terminals is also possible.

A fourth control signal generating circuit 44 applies a fourth control signal S4 through high frequency cutoff resistance 14 to the source/drain terminal of MOS transistor 13. A fifth control signal generating circuit 45 applies a fifth control signal S5 through high frequency cutoff resistance 15 to the gate of MOS transistor 13. Both control signals S4 and S5 are a DC voltage that is any one of, a combination of any two of, or all three of the temperature compensation control signal, external voltage frequency control signal, and variation compensation control signal.

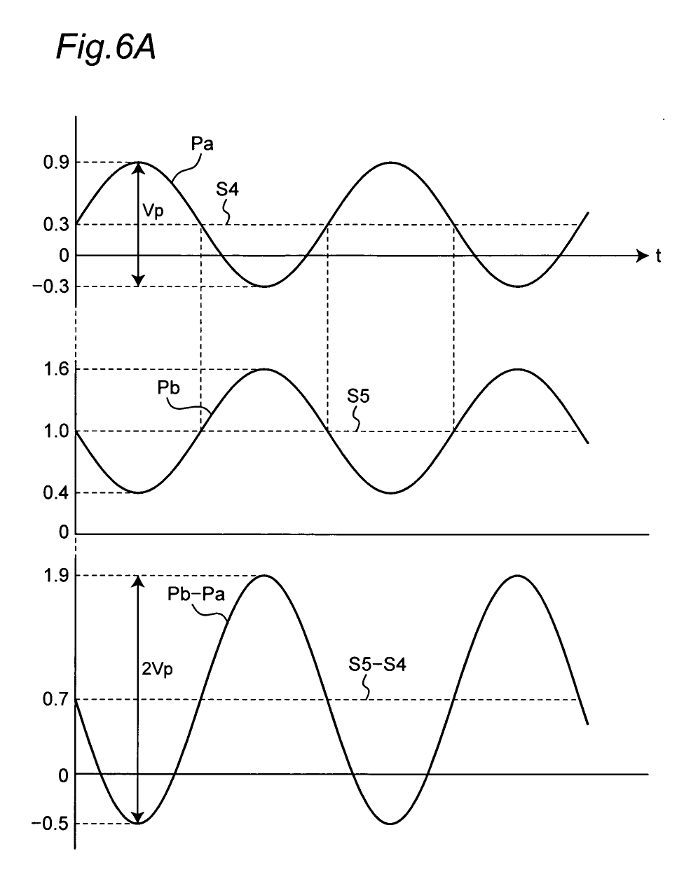

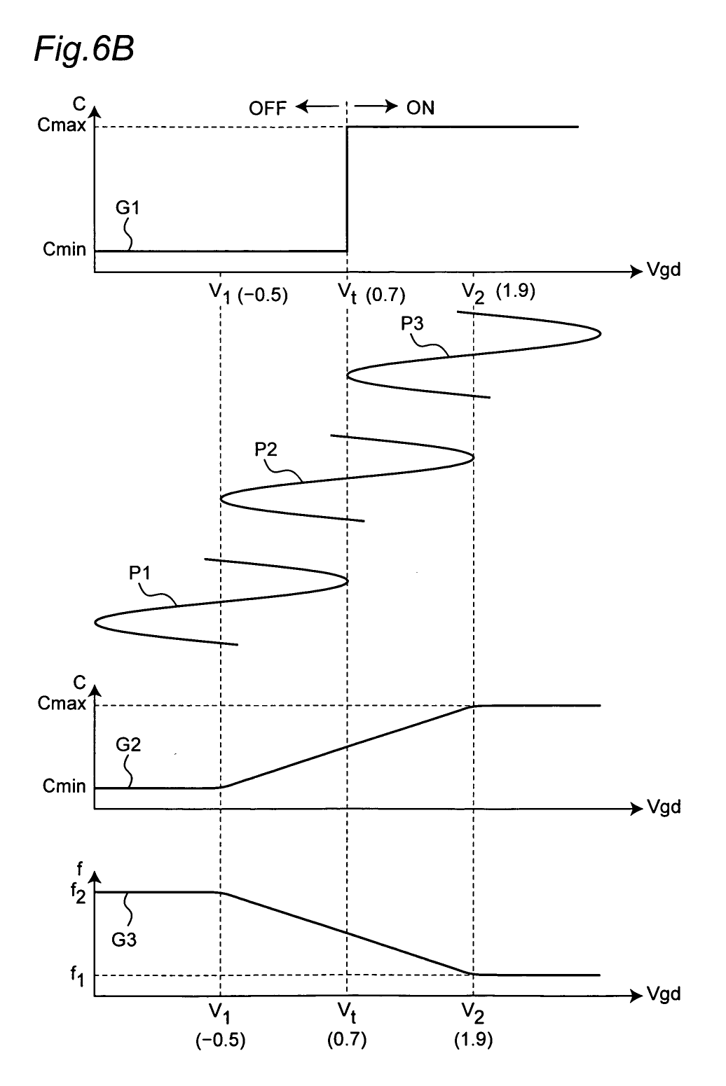

As in the foregoing first embodiment, the phase of the signals applied to the gate of the MOS transistor 13 is shifted 180° from the phase of the signals applied to the source/drain terminal as shown in FIG. 6A. If sine signal Pa is applied to the gate, sine signal Pb is applied to the source/drain terminal, and Pa and Pb are amplitude Vp peak-to-peak, a sine wave of amplitude 2Vp appears between the gate and source/drain terminals (see FIG. 6A). Due to the mirror effect, the capacity of the MOS transistor 13 is equivalent to approximately twice the capacitance. As a result, if the frequency characteristic is comparable to that of the foregoing first embodiment, the size of MOS transistor 13 can be arranged to present approximately ¼ the capacitance of MOS transistor compared to the capacitance of MOS transistor that was necessary in the first embodiment. In terms of area, MOS transistor 13 can be achieved in approximately ⅛ of the area.

Conversely, if the load capacitance of this second embodiment is the same as that of the first embodiment, the range of the gate voltage Vg relative to the same variable capacitance range Cmin-Cmax can be increased, as indicated by C-V characteristic waveform G2 shown in FIG. 6B. More specifically, the dynamic range can be increased. The f-V characteristic of the oscillation frequency in this case is denoted by waveform G3 in FIG. 6B.

FIG. 5B is a circuit diagram of a first variation of this second embodiment of the invention. In the arrangement shown in FIG. 5A the first DC cut-off capacitance 8 and second DC cut-off capacitance 9 are disposed between the crystal oscillator 3 and MOS transistor 13, but in this first variation the first DC cut-off capacitance 8 and second DC cut-off capacitance 9 are disposed between the crystal oscillator 3 and amplifier 2 as shown in FIG. 5B. Operation of the circuit shown in FIG. 5B is identical to the circuit shown in FIG. 5A.

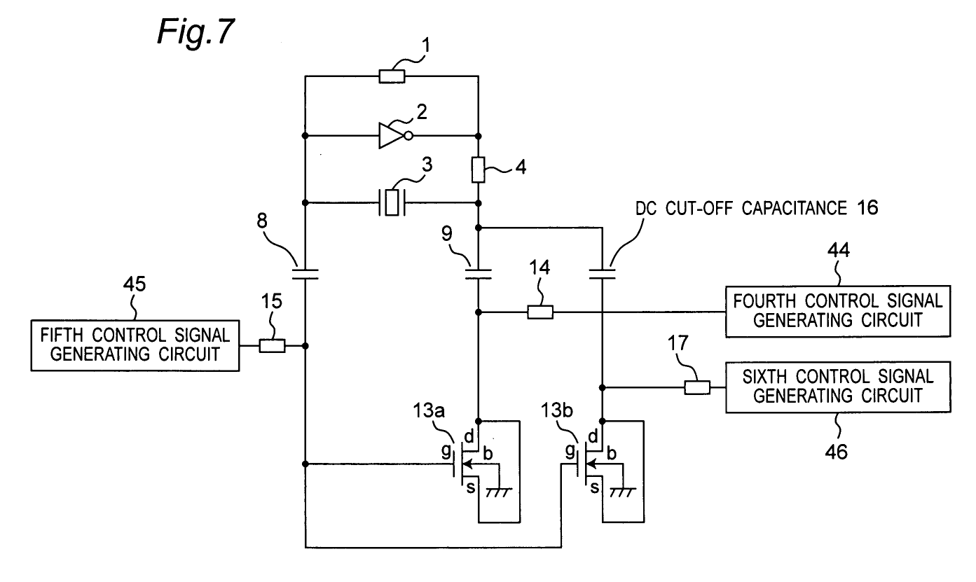

FIG. 7 is a schematic circuit diagram of a second variation of the second embodiment. This variation differs from the arrangement shown in FIG. 5A in that MOS transistor 13 is split into MOS transistor 13a and MOS transistor 13b with MOS transistor 13a connected in the same way as MOS transistor 13 in FIG. 5A. MOS transistor 13b is serially connected to a third DC cut-off capacitance 16. The serial connection of DC cut-off capacitance 16 and MOS transistor 13b is also connected parallel to the serial connection of DC cut-off capacitance 9 and MOS transistor 13a.

A sixth control signal generating circuit 46 is also connected through high frequency cutoff resistance 17 to the source/drain terminal of MOS transistor 13b. This sixth control signal generating circuit 46 outputs control signal S6, which is a DC voltage. This control signal S6 provides the function of any one of, any two of, or all three of the temperature compensation control signal, external voltage frequency control signal, and variation compensation control signal.

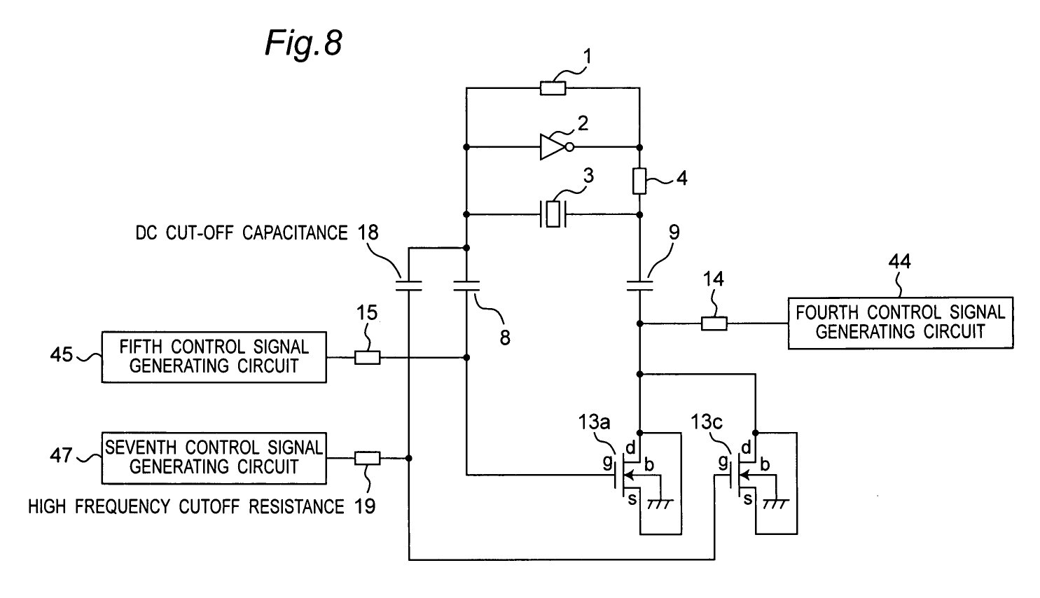

FIG. 8 is a schematic circuit diagram of a third variation of the second embodiment. This variation differs from the arrangement shown in FIG. 5A in that MOS transistor 13 is split into MOS transistor 13a and MOS transistor 13c with MOS transistor 13a connected in the same way as MOS transistor 13 in FIG. 5A. MOS transistor 13c is serially connected to a fourth DC cut-off capacitance 18. The serial connection of DC cut-off capacitance 18 and MOS transistor 13c is also connected parallel to the serial connection of DC cut-off capacitance 8 and MOS transistor 13a.

Additionally, a seventh control signal generating circuit 47 is connected to the gate of MOS transistor 13c through high frequency cutoff resistance 19. This seventh control signal generating circuit 47 outputs control signal S7, which is a DC voltage. This control signal S7 provides the function of any one of, any two of, or all three of the temperature compensation control signal, external voltage frequency control signal, and variation compensation control signal.

By thus splitting the MOS transistor 13 into plural MOS transistors as shown in FIG. 7 and FIG. 8, the temperature compensation control signal, external voltage frequency control signal, and variation compensation control signal can be controlled more independently.

The DC cut-off capacitances 8 and 9 could also be omitted.

### Embodiment 3

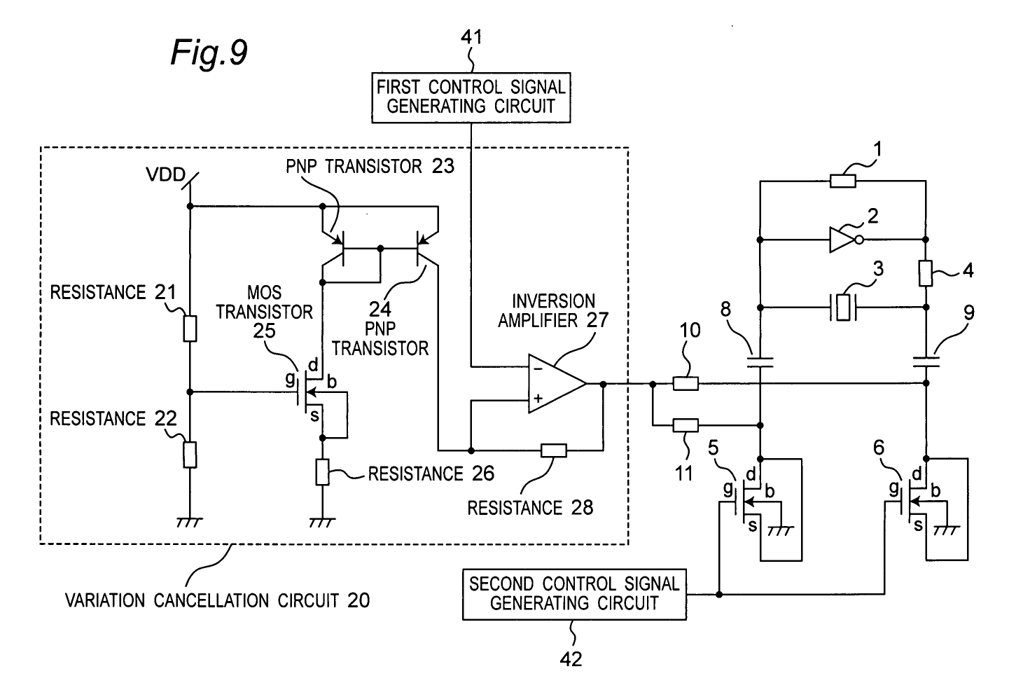

FIG. 9 is a schematic circuit diagram of a voltage controlled oscillator according to a third embodiment of the present invention. As shown in FIG. 9, this embodiment differs from the arrangement shown in FIG. 1 in that a variation cancellation circuit 20 is additionally disposed between the first control signal generating circuit 41 and high frequency cutoff resistance 10.

This variation cancellation circuit 20 is composed of MOS transistor 25, resistances 21, 22,26, 28, transistors 23, 24, and inversion amplifier 27. MOS transistor 25 is rendered near MOS transistors 5 and 6 and has the same IC structure and characteristics as MOS transistors 5 and 6. Voltage change due to temperature or variations in the MOS transistor 25 is inverted by the inversion amplifier 27 to a negative change. Voltage change due to temperature or variations in MOS transistors 5 and 6 appears as a positive at the drain and source of MOS transistors 5 and 6. These positive and negative changes are mutually cancelling, and signals not containing voltage change due to temperature or manufacturing variations thus appear at the gate of MOS transistors 5 and 6.

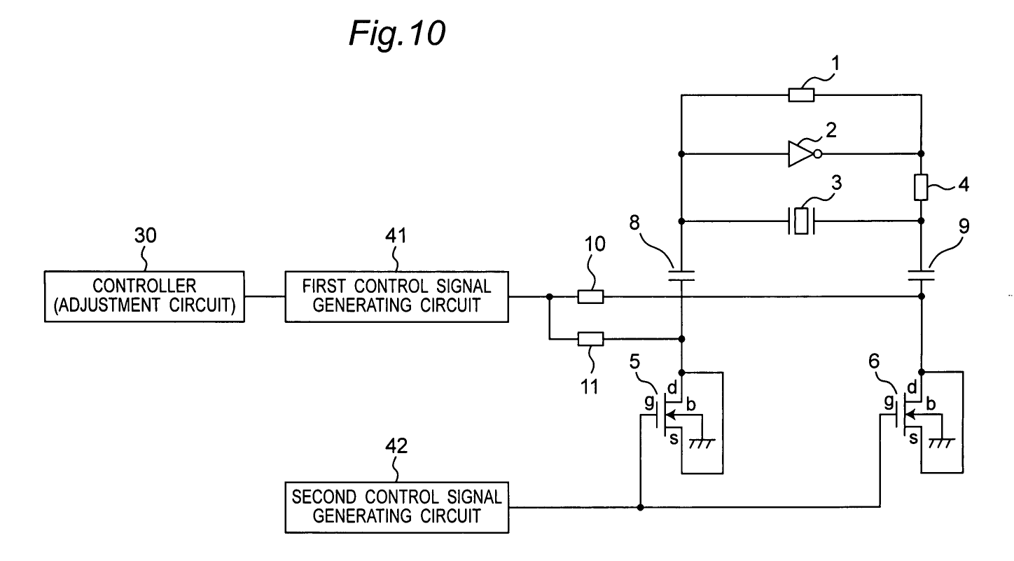

FIG. 10 shows a variation of the third embodiment. A controller (adjustment circuit) 30 is provided instead of variation cancellation circuit 20.

This controller (adjustment circuit) 30 has memory, and can be disposed either before or after the first control signal generating circuit 41. Variation in the threshold voltage of the MOS transistors 5 and 6 introduced in the dispersion process during manufacture, and change relative to temperature, are detected, and the voltage required to cancel these variations and temperature changes is detected and written to memory prior to shipping. This memory is PROM or other nonvolatile memory device.

The variation cancellation circuit 20 shown in FIG. 9 could also be used in the first and second embodiments and variations thereof. Likewise, the controller (adjustment circuit) 30 shown in FIG. 10 could also be used in the first and second embodiments and variations thereof.

Note, further, that the MOS transistors described above could be NMOS or PMOS transistors.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A voltage controlled oscillator having a pair of terminals for connection to a piezoelectric vibrator, comprising:
an amplifier of which the input and output sides are separately connected to the terminals of said terminal pair for connection to said piezoelectric vibrator;
a MOS transistor having source, drain, and gate terminals with said source terminal connected to said drain terminal;
a capacitance element inserted between one side of said amplifier and said source terminal of said MOS transistor;
a first control signal generating circuit operable to supply an electric control signal to said source terminal of said MOS transistor; and
a second control signal generating circuit operable to supply an electric control signal to said gate terminal of said MOS transistor.

2. A voltage controlled oscillator having a pair of terminals for connection to a piezoelectric vibrator, comprising:
an amplifier of which the input and output sides are separately connected to the terminals of said terminal pair for connection to said piezoelectric vibrator;
first and second MOS transistors each having source, drain, and gate terminals with said source terminal connected to said drain terminal;
a first capacitance element inserted between one side of said amplifier and said source terminal of said first MOS transistor;
a second capacitance element inserted between one side of said amplifier and said source terminal of said second MOS transistor;
a first control signal generating circuit operable to supply an electric control signal to said source terminal of at least one of said first and second MOS transistors; and
a second control signal generating circuit operable to supply an electric control signal to said gate terminal of at least one of said first and second MOS transistors.

3. The voltage controlled oscillator described in claim 2, wherein said first and second capacitance elements are commonly connected to one side of said amplifier.

4. A voltage controlled oscillator having a pair of terminals for connection to a piezoelectric vibrator, comprising:
an amplifier of which the input and output sides are separately connected to the terminals of said terminal pair for connection to said piezoelectric vibrator;
first and second MOS transistors each having source, drain, and gate terminals with said source terminal connected to said drain terminal;
a first capacitance element inserted between one side of said amplifier and said source terminals of said first and second MOS transistors;
a second capacitance element inserted between the other side of said amplifier and said gate terminal of said first MOS transistor;
a third capacitance element inserted between said other side of said amplifier and said gate terminal of said second MOS transistor;
a first control signal generating circuit operable to supply an electric control signal to said source terminal of at least one of said first and second MOS transistors; and
a second control signal generating circuit operable to supply an electric control signal to said gate terminal of at least one of said first and second MOS transistors.

5. The voltage controlled oscillator described in claim 4, further comprising a third control signal generating circuit operable to supply an electric control signal to said gate terminal of at least one of said first and second MOS transistors.

6. A voltage controlled oscillator having a pair of terminals for connection to a piezoelectric vibrator, comprising:
an amplifier of which the input and output sides are separately connected to the terminals of said terminal pair for connection to said piezoelectric vibrator;
first, second, third, and fourth MOS transistors each having source, drain, and gate terminals with said source terminal connected to said drain terminal;
a first capacitance element inserted between one side of said amplifier and said source terminals of said first and second MOS transistors;
a second capacitance element inserted between the other side of said amplifier and said source terminals of said third and fourth MOS transistors;
a first control signal generating circuit operable to supply an electric control signal to said source terminals of either said first and second MOS transistor pair or said third and fourth MOS transistor pair;
a second control signal generating circuit operable to supply an electric control signal to said gate terminal of at least one of said first and third MOS transistors; and
a third control signal generating circuit operable to supply an electric control signal to said gate terminal of at least one of said second and fourth MOS transistors.

7. The voltage controlled oscillator described in claim 1, wherein said voltage controlled oscillator has a piezoelectric vibrator connected to said terminals for connection to a piezoelectric vibrator.

8. The voltage controlled oscillator described in claim 7, wherein said piezoelectric vibrator is a crystal vibrator.

9. The voltage controlled oscillator described in claim 1, wherein said first control signal is a signal containing at least one of a temperature compensation control signal, external voltage frequency control signal, and deviation compensation control signal.

10. The voltage controlled oscillator described in claim 1, wherein said second control signal is a signal containing at least one of a temperature compensation control signal, external voltage frequency control signal, and deviation compensation control signal.

11. The voltage controlled oscillator described in claim 5, wherein said third control signal is a signal containing at least one of a temperature compensation control signal, external voltage frequency control signal, and deviation compensation control signal.

12. The voltage controlled oscillator described in claim 6, wherein said third control signal is a signal containing at least one of a temperature compensation control signal, external voltage frequency control signal, and deviation compensation control signal.

13. The voltage controlled oscillator described in claim 1, further comprising an amplitude control circuit disposed to the source/drain terminal of said first MOS transistor, or to the source/drain terminal of said second MOS transistor.

14. The voltage controlled oscillator described in claim 1, further comprising a variation cancellation circuit disposed to said first control signal generating circuit or to said second control signal generating circuit.

15. The voltage controlled oscillator described in claim 1, further comprising a controller having memory storing a table for variation cancellation disposed to said first control signal generating circuit or to said second control signal generating circuit.

16. The voltage controlled oscillator described in claim 13, wherein said variation cancellation circuit comprises a third MOS transistor configured substantially identically to said first or second MOS transistor, and applies to the drain terminal of said first MOS transistor or second MOS transistor a voltage generated by inverting and amplifying current generated by said third MOS transistor.

17. The voltage controlled oscillator described in claim 14, wherein said variation cancellation circuit comprises a third MOS transistor configured substantially identically to said first or second MOS transistor, and applies to the drain terminal of said first MOS transistor or second MOS transistor a voltage generated by inverting and amplifying current generated by said third MOS transistor.
